(19) United States
(12) Patent Application Publication
(10) Pub. No.: US 2024/0048071 A1
(43) Pub. Date: Feb. 8, 2024

(54) METHOD AND APPARATUS FOR OPERATING AT LEAST ONE SWITCHING DEVICE OF A POWER CONVERTER FOR AN ELECTRICAL AXLE DRIVE OF A MOTOR VEHICLE, POWER CONVERTER SYSTEM FOR AN ELECTRICAL AXLE DRIVE OF A MOTOR VEHICLE, ELECTRICAL AXLE DRIVE FOR A MOTOR VEHICLE AND MOTOR VEHICLE

(71) Applicant: ZF Friedrichshafen AG, Friedrichshafen (DE)

(72) Inventor: Fabian Hohmann, Hofbieber (DE)

(73) Assignee: ZF Friedrichshafen AG, Friedrichshafen (DE)

(21) Appl. No.: 18/365,810

(22) Filed: Aug. 4, 2023

(30) Foreign Application Priority Data
Aug. 4, 2022 (DE) 102022208101.3

(51) Int. Cl. H02M 7/5395; H02M 1/08; H02M 1/00; B60L 50/51

(52) U.S. Cl. CPC H02M 7/5395; H02M 1/082; H02M 1/0009; B60L 50/51; B60L 2210/42

(57) ABSTRACT

A method for operating at least one switching device of a power converter includes actuating a first switching element of the switching device by a first pulse-width modulation signal when the current flux in the switching device lies below a predefined threshold value, or actuating a second switching element of the switching device by a second pulse-width modulation signal when a current flux in the switching device exceeds the predefined threshold value. At least one parameter of the first pulse-width modulation signal and/or of the second pulse-width modulation signal is adjusted according to the time point of achievement of the predefined threshold value.

### CROSS-REFERENCE TO RELATED APPLICATION

This application claims priority to German Application No. DE 10 2022 208 101.3, filed on Aug. 4, 2022, the entirety of which is hereby fully incorporated by reference herein.

### FIELD

The present invention relates to a method for operating at least one switching device of a power converter for an electrical axle drive of a motor vehicle, a corresponding apparatus, a power converter system for an electrical axle drive of a motor vehicle, an electrical axle drive for a motor vehicle and a motor vehicle.

### BACKGROUND AND SUMMARY

A parallel circuit, for example, of different types of power semiconductors or switches having different types of semiconductors can be provided in a traction converter. For this type of parallel operation of two different switches, various actuation methods for the execution of a switchover between different types are employed. Active short-circuiting is, for example, a known method for the torque-free emergency operation of permanently excited synchronous machines.

In this context, the present invention provides an improved method for operating at least one switching device of a power converter for an electrical axle drive of a motor vehicle, an improved apparatus for operating at least one switching device of a power converter for an electrical axle drive of a motor vehicle, an improved power converter system for an electrical axle drive of a motor vehicle, an improved electrical axle drive for a motor vehicle and an improved motor vehicle, as disclosed herein. Advantageous configurations also proceed from the following description.

Advantages which are achievable by means of the approach envisaged are particularly provided in that, in a power converter for an electrical axle drive of a motor vehicle, the most accurate possible switchover between different types of semiconductors, also described herein as switching elements, can be achieved with limited or minimal errors in the voltage-time integral. To this end, for example, discontinuous pulse-width modulation is employed for the switchover of power semiconductor types or, in other words, a switchover between switching elements which are mutually electrically connected in parallel, in order to minimize current errors and, additionally or alternatively, for the accurate definition of the switchover time point. The parallel electrical connection and temporally separate operation of two different types of switching elements in a traction converter or, in other words, a power converter, can permit a high degree of efficiency, with limited semiconductor costs. Parallel operation of switching elements of different designs can permit the embodiment of an advantageous actuation method, particularly a temporally separate actuation, also described as XOR actuation, for the switching elements of the at least one switching device of the power converter.

A method is proposed for operating at least one switching device of a power converter for an electrical axle drive of a motor vehicle, wherein the switching device comprises at least two parallel-connected or connectable switching elements, which are configured as different types of switching elements, wherein the method comprises the following step:

Actuation of a first switching element of the switching device by a first pulse-width modulation signal, if the current flux in the switching device lies below a predefined threshold value, or of a second switching element of the switching device by a second pulse-width modulation signal, if a current flux in the switching device exceeds the predefined threshold value, wherein at least one parameter of the first pulse-width modulation signal and/or of the second pulse-width modulation signal is adjusted according to the time point of achievement of the predefined threshold value.

The motor vehicle can be, for example, a land vehicle, particularly a passenger car, a motorcycle, a service vehicle or similar. The power converter can be embodied in the form of a power inverter, or an inverter. The power converter can also be described as a traction converter. The power converter can be configured to convert a direct electric current from an electrical energy store of the motor vehicle into an alternating current for an electrical machine of the electrical axle drive of the motor vehicle. By the execution of the method, a parallel operation of both switching elements of the switching device can be permitted, wherein the two switching elements are actuated in a temporally separate manner. In particular, in each case, a single switching element can intermittently accommodate the entire current flux in the switching device.

According to one embodiment, in the actuation step, as the at least one parameter, a pulse-pause ratio and, additionally or alternatively, a duty factor of the first pulse-width modulation signal and, additionally or alternatively, of the second pulse-width modulation signal can be variably adjusted. Such an embodiment provides an advantage in that, particularly by discontinuous pulse-width modulation, a reliable and accurate switchover between the switching elements can be achieved.

Additionally, in the actuation step, as the at least one parameter, a pulse duration of at least one pulse and, additionally or alternatively, a pulse interval between pulses and, additionally or alternatively a pulse number of pulses of the first pulse-width modulation signal and, additionally or alternatively, of the second pulse-width modulation signal can be varied. Such an embodiment provides an advantage, in that pulse-width modulation can be adapted in an appropriate manner, such that current errors associated with the switchover between switching elements are minimized and, additionally or alternatively, an accurate switchover is permitted.

Moreover, in the actuation step, as the at least one parameter, a pulse duration of a final pulse of one of the pulse-width modulation signals prior to the achievement of the predefined threshold value is varied, such that a first pulse of the other pulse-width modulation signal commences at the time of achievement of the predefined threshold value. Such an embodiment provides an advantage, in that the respective switch-on pulse for one of the switching elements coincides with the switchover current or, in other words, with the achievement of the threshold value.

Additionally, in the actuation step, as the least one parameter, a pulse duration of pulses of the first pulse-width modulation signal and, additionally or alternatively, of the second pulse-width modulation signal can be adjusted such that a sum of values by which pulses can be shortened and a sum of the values by which pulses can be extended are equal. Such an embodiment provides an advantage, in that a load equalization between switching elements can be achieved. In particular, any load unbalance between high-side and low-side switches can be prevented on the grounds that, in this manner, the switch-on times of switches can be equalized. If, for example, the first pulse on the high side is extended, the second pulse can be shortened.

According to one embodiment, in the actuation step, as the at least one parameter, a pulse number of pulses of one of the pulse-width modulation signals prior to the achievement of the predefined threshold value can be varied such that a first pulse of the other pulse-width modulation signal commences at the time of achievement of the predefined threshold value. Such an embodiment provides an advantage in that, in this manner, it can also be reliably achieved that the respective switch-on pulse for one of the switching elements coincides with the switchover current or, in other words with the achievement of the threshold value.

The method can also comprise a step for the read-in of a current flux signal, which represents the current flux in the switching device as an estimated value, as a measured value, or as a combination of an estimated value and a measured value. Such an embodiment provides an advantage, in that an accurate determination of the switchover time point, or of the achievement of the threshold value, can be executed as early or as promptly as possible.

The approach proposed herein further provides an apparatus, which is configured to execute, actuate or implement the steps of a variant of the method proposed herein in corresponding devices. By this variant of embodiment of the invention in the form of an apparatus, an object of the invention can be fulfilled in a rapid and efficient manner.

An apparatus can be an electrical device which processes electrical signals, for example sensor signals, and generates a control signal output in accordance therewith. The apparatus can comprise one or more appropriate interfaces, which can be configured in a hardware-based or software-based form. In a hardware-based embodiment, the interfaces can be, for example, an element of an integrated circuit in which functions of the apparatus are implemented. The interfaces can also be dedicated integrated circuits, or can be at least partially comprised of discrete components. In a software-based embodiment, the interfaces can be software modules which are present, for example, on a microcontroller, in addition to other software modules.

A power converter system is also proposed for an electrical axle drive of a motor vehicle, wherein the power converter system comprises an embodiment of the apparatus described herein and the power converter, wherein the power converter comprises the at least one switching device which comprises the at least two parallel-connected switching elements, which are different types of switching elements.

The power converter can comprise DC terminals for a direct electric current from an electrical energy store of the motor vehicle, a DC link capacitor, which is electrically connected to the DC terminals, AC terminals for the delivery of an alternating electric current for an electrical machine of the electrical axle drive and a plurality of switching devices, wherein the switching devices are configured to convert the direct current into the alternating current. In particular, by the execution of a variant of the method described herein, each switching device of the power converter can be operated.

According to one embodiment, the first switching element can be a field effect transistor, a metal oxide semiconductor field effect transistor or a silicon carbide metal oxide semiconductor field effect transistor. The second switching element can be a bipolar transistor, a bipolar transistor with an insulated gate electrode, or a silicon bipolar transistor with an insulated gate electrode. Such an embodiment provides an advantage in that, by means of a parallel-connected circuit of such switching elements, efficiency can be enhanced with limited semiconductor costs.

The invention further relates to an electrical axle drive for a motor vehicle having at least one electrical machine, a transmission device, and an embodiment of a power converter system described herein.

The power converter can be embodied in the form of a power inverter or an inverter. By the employment of the power converter, the alternating electric current required for operating the electrical machine can be supplied. By the employment of the transmission device, a torque delivered by the electrical machine can be converted into a drive torque for driving at least one wheel of the motor vehicle. The transmission device can be a transmission for reducing the rotational speed of the electrical machine, and can optionally comprise a differential.

The invention further relates to a motor vehicle having an embodiment of a power converter system described herein and, additionally or alternatively, having an embodiment of an electrical axle drive described herein.

Correspondingly, a motor vehicle can comprise a power converter system described herein and, additionally or alternatively, an electrical axle drive described herein.

A computer program or computer program product is also advantageous, having program code which can be saved on a machine-readable medium such as a semiconductor memory, a hard disk memory or an optical memory, and employed for the execution of the method according to one of the above-mentioned embodiments, when the program is run on a computer or an apparatus.

The invention is described in greater detail, for exemplary purposes, with reference to the drawings.

### BRIEF DESCRIPTION OF THE DRAWINGS

FIG. 1 shows a schematic representation of one exemplary embodiment of a motor vehicle;

FIG. 2 shows a schematic partial representation of one exemplary embodiment of an electrical axle drive of a motor vehicle;

FIG. 3 shows a schematic representation of one exemplary embodiment of an apparatus for operating at least one switching device of a power converter for an electrical axle drive of a motor vehicle;

FIG. 4 shows a flow diagram of one exemplary embodiment of a method for operating at least one switching device of a power converter for an electrical axle drive of a motor vehicle;

FIG. 5 shows a schematic representation of a switching device of the power converter according to FIG. 1 or FIG. 2;

FIG. 6 shows a schematic time-current intensity diagram for the operation of the at least one switching device according to FIG. 5;

FIG. 7 shows a section of the diagram according to FIG. 6;

FIG. 8 shows a schematic time-current intensity diagram for the operation of the at least one switching device according to FIG. 5;

FIG. 9 shows a schematic time-current intensity diagram for the operation of the at least one switching device according to FIG. 5; and

FIG. 10 shows a schematic time-current intensity diagram for the operation of the at least one switching device according to FIG. 5.

### DETAILED DESCRIPTION

In the following description of preferred exemplary embodiments of the present invention, elements in the various figures having a similar function are identified by identical or similar reference symbols, and any repeated description of these elements is omitted.

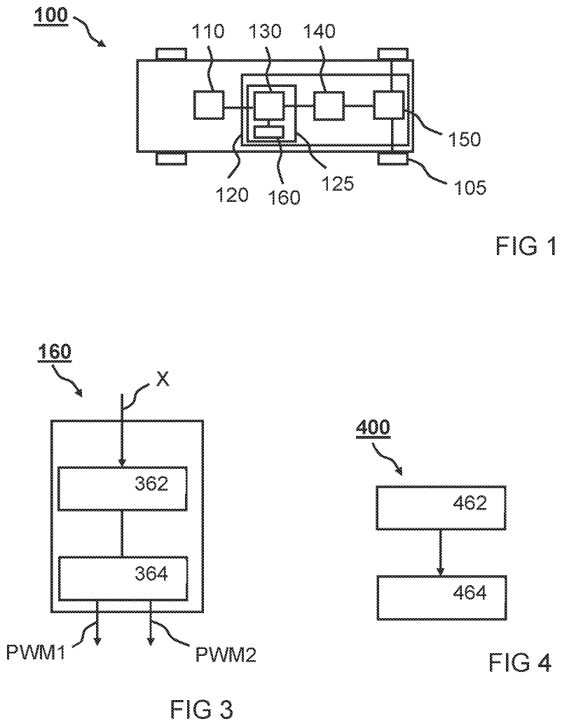

FIG. 1 shows a schematic representation of one exemplary embodiment of a motor vehicle 100. Of the motor vehicle 100, in the representation according to FIG. 1, wheels 105, wherein four wheels 105 are represented by way of an example only, an electrical energy store 110, for example a battery, and an electrical axle drive 120 are shown. The electrical axle drive 120 comprises a power converter system 125, an electrical machine 140 and a transmission device 150. The power converter system 125 comprises a power converter 130 and an operating apparatus 160 or apparatus for operating at least one switching device of the power converter 130.

Electrical energy for operating the electrical machine 105 is supplied by an energy supply device, in this case the electrical energy store 110. The electrical energy store 110 is configured to supply a direct current which, by the employment of a power converter 130 of the electrical axle drive 120, is converted into an alternating current, for example a three-phase alternating current, and is delivered to the electrical machine 140. A shaft which is driven by the electrical machine 140 is coupled to at least one wheel 105 of the motor vehicle 100, either directly or by means of the transmission device 150. The motor vehicle 100 can thus be propelled by the employment of the electrical machine 140. According to one exemplary embodiment, the electrical axle drive comprises a housing, in which at least the power converter 130 of the power converter system 125, the electrical machine 140 and the transmission device 150 are arranged.

The power converter system 125 in particular, and the components thereof, are addressed in greater detail with reference to the following figures.

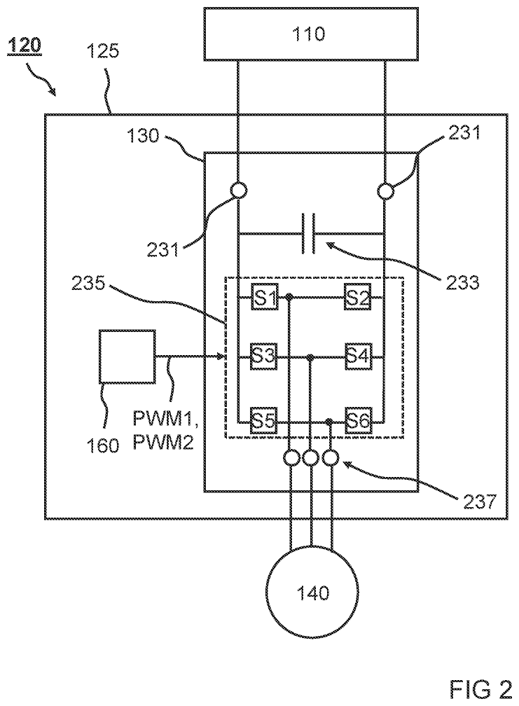

FIG. 2 shows a schematic partial representation of one exemplary embodiment of an electrical axle drive 120 of a motor vehicle. The electrical axle drive 120 corresponds, or is similar to the electrical axle drive according to FIG. 1. Of the electrical axle drive 120, the partial representation according to FIG. 2 shows the power converter system 125 and the electrical machine 140. Additionally to the electrical axle drive 120, the electrical energy store 110 is also represented in FIG. 2. The power converter system 125 comprises the power converter 130 and the operating apparatus 160. The power converter 130 comprises DC terminals 231, a DC link capacitor 233, a plurality of switching devices 235 and AC terminals 237. The operating apparatus 160 is connected to the power converter 130 with a signal transmission capability. More precisely, the operating apparatus 160 is connected to the switching devices 235 of the power converter 130 with a signal transmission capability. The operating apparatus 160 is configured to deliver an output of the first pulse-width modulation signal PWM1 and the second pulse-width modulation signal PWM2 to at least one of the switching devices 235 of the power converter 130.

The DC terminals 231 are provided for a direct electric current from the electrical energy store 110 of the motor vehicle. In other words, the power converter 130 is connected or connectable to the electrical energy store 110 via the DC terminals 231. The DC link capacitor 233 is electrically connected to the first of the DC terminals 231 and to the second of the DC terminals 231. The AC terminals 237 are provided for the supply of an alternating electric current for the electrical machine 140 of the electrical axle drive. In other words, the power converter 130 is connectable or connected to the electrical machine 140 via the AC terminals 237. The DC terminals 231 and/or the AC terminals 237, for example, are respectively configured to accommodate one end of a power cable, and to execute the mechanical and electrical contact-connection thereof, for example by means of screwing, clamping or soldering.

The switching devices 235 are configured to convert direct current into an alternating current. At least or each of the switching devices 235 comprises at least two parallel-connected switching elements, wherein these are different types of switching elements. The switching devices 235 are also addressed in greater detail with reference to the following figures. According to the exemplary embodiment represented here, the power converter 130, by way of an example only, comprises six switching devices 235, in this case a first switching device S1, a second switching device S2, a third switching device S3, a fourth switching device S4, a fifth switching device S5 and a sixth switching device S6. The switching devices 235 or S1, S2, S3, S4, S5 and S6 are interconnected in a B6 bridge circuit. A first of the DC terminals 231 is electrically connected to a first terminal of the first switching device S1, to a first terminal of the third switching device S3, and to a first terminal of the fifth switching device S5. A second of the DC terminals 231 is electrically connected to a first terminal of the second switching device S2, to a first terminal of the fourth switching device S4 and to a first terminal of the sixth switching device S6. A first of the AC terminals 237 is electrically connected to a second terminal of the first switching device S1 and to a second terminal of the second switching device S2. A second of the AC terminals 237 is electrically connected to a second terminal of the third switching device S3 and to a second terminal of the fourth switching device S4. A third of the AC terminals 237 is electrically connected to a second terminal of the fifth switching device S5 and to a second terminal of the sixth switching device S6.

According to one exemplary embodiment, the power converter 130 can be operated in the reverse direction, such that the electrical machine 140 can be employed as a generator for charging the electrical energy store 110.

FIG. 3 shows a schematic representation of one exemplary embodiment of an operating apparatus 160 or an apparatus 160 for operating at least one switching device of a power converter for an electrical axle drive of a motor vehicle. The operating apparatus 160 corresponds, or is similar to the operating apparatus according to one of the figures described above. The operating apparatus 160 is configured to operate at least one switching device, which comprises at least two parallel-connected switching elements of different types.

The operating apparatus 160 comprises an actuation device 364. The actuation device 364 is configured to actuate a first switching element of the switching device by means of a first pulse-width modulation signal PWM1, if a current flux in the switching device lies below a predefined threshold value, or to actuate a second switching element of the switching device by means of a second pulse-width modulation signal PWM2, if the current flux in the switching device exceeds the predefined threshold value. The actuation device 364 is configured to adjust at least one parameter of the first pulse-width modulation signal PWM1 and/or of the second pulse-width modulation signal PWM2, according to a time of achievement of the predefined threshold value.

According to one exemplary embodiment, the operating apparatus 160 also comprises read-in device 362. The read-in device 362 is configured for the read-in of a current flux signal X and the delivery thereof to the actuation device 364. The current flux signal X represents the current flux in the switching device, as an estimated value, as a measured value, or as a combination of an estimated value and a measured value.

FIG. 4 shows a flow diagram of an exemplary embodiment of a method 400 for operating at least one switching device of a power converter for an electrical axle drive of a motor vehicle. The operating method 400 is executable for the operation of at least one of the switching devices of the power converter according to one of the figures described above, or of a similar power converter. The operating method 400 is thus executable for operating at least one switching device which comprises at least two parallel-connected or connectable switching elements of different types. The operating method 400 is executable by the employment of the operating apparatus according to one of the figures described above, or a similar operating apparatus.

The operating method 400 comprises an actuation step 464. In the actuation step 464, a first switching element of the switching device is actuated by means of a first pulse-width modulation signal, if a current flux in the switching device lies below a predefined threshold value, or a second switching element of the switching device is actuated by means of a second pulse-width modulation signal, if a current flux in the switching device exceeds the predefined threshold value. At least one parameter of the first pulse-width modulation signal and/or of the second pulse-width modulation signal is adjusted, according to a time of achievement of the predefined threshold value.

According to one exemplary embodiment, the operating method 400 also comprises a read-in step 462. In the read-in step 462, a current flux signal is read-in which represents the current flux in the switching device as an estimated value, as a measured value, or as a combination of an estimated value and a measured value.

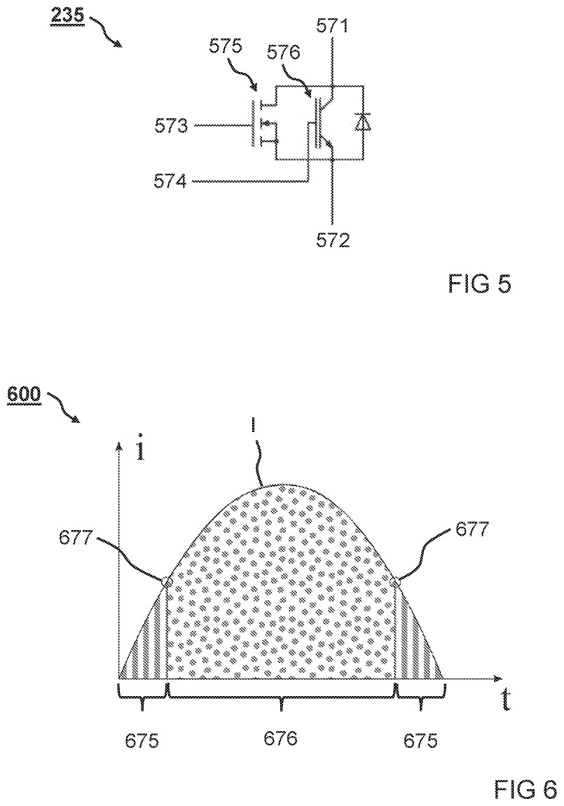

FIG. 5 shows a schematic representation of a switching device 235 of the power converter according to FIG. 1 or FIG. 2. In particular, in the switching device 235 represented in FIG. 5, this is one of the first to sixth switching devices according to FIG. 2. The switching device 235 in FIG. 5 is shown in a topological representation.

The switching device 235, according to the exemplary embodiment represented here, comprises two electrically parallel-connected switching elements 575 and 576 of different types, a first switching element 575 of one type and a second switching element 570 of another type. The switching device 235 further comprises a first terminal 571, a second terminal 572, a first control terminal 573 and a second control terminal 574, wherein the control terminals 573 and 574 or gate terminals are employed for controlling the current flux in the switching device 235 between the first terminal 571 and the second terminal 572. The first control terminal 573 is assigned to the first switching element 575. The first pulse-width modulation signal can be applied to the first control terminal 573. The second control terminal 574 is assigned to the second switching element 576. The second pulse-width modulation signal can be applied to the second control terminal 574.

According to the exemplary embodiment represented here, the first switching element 575 is a field effect transistor and the second switching element is a bipolar transistor. More precisely, the first switching element 575, for example, is a metal oxide field effect transistor, and the second switching element 576, for example, is a bipolar transistor with an insulated gate electrode. In particular, the first switching element 575 is a silicon carbide metal oxide semiconductor field effect transistor, and the second switching element 576 is a silicon bipolar transistor with an insulated gate electrode.

FIG. 6 shows a schematic time-current intensity diagram 600 for the operation of the at least one switching device according to FIG. 5. Time t is plotted on the x-axis of the diagram 600, and the current intensity i is plotted on the y-axis of the diagram 600. A sinusoidal current curve I is plotted in the diagram 600. By way of illustration, in the diagram 600, a first actuation region 675 for the actuation of the first switching element of the switching device and a second actuation region 676 for the actuation of the second switching element of the switching device are represented. The diagram 600 further shows switchover regions 677, in which the predefined threshold value is achieved, and a switchover is executed between the actuation of the first switching element by means of the first pulse-width modulation signal and the actuation of the second switching element by means of the second pulse-width modulation signal.

In other words, FIG. 6 illustrates a potential embodiment of an operating method, as per the method according to FIG. 4, in the form of a XOR actuation of the switching elements of the switching device. In the first actuation region 675, the first switching element, which is embodied, for example, as a silicon carbide MOSFET, is conductive, whereas the second actuation region 676 is controlled by the second switching element, which is embodied, for example, as a silicon IGBT. XOR actuation permits a number of advantages, including e.g. optimized gate resistances, the necessity for only one current sensor, etc. According to exemplary embodiments of the operating apparatus described herein, and/or of the operating method described herein, an accurate switchover between semiconductor types or between switching elements in the circled switchover regions 677 is permitted, and can be achieved notwithstanding the discretization of the sine wave of the current curve I at the switching frequency.

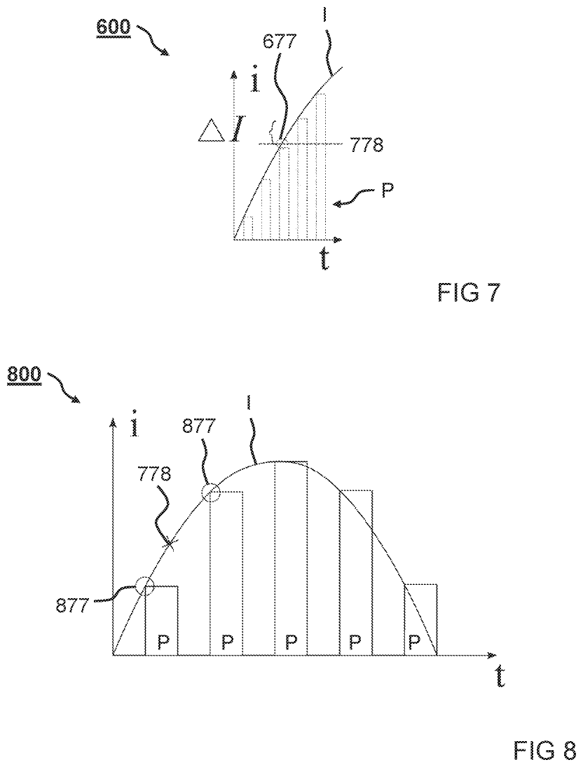

FIG. 7 shows a section of the diagram 600 according to FIG. 6. The section represented in FIG. 7 comprises one of the switchover regions 677 and part of the current curve I. The predefined threshold value 778 is further represented. FIG. 7 illustrates the current of a semiconductor or switching element of the switching device, discretized in the form of a pulse P of a pulse-width modulation signal, and a current error ΔI associated with a switchover at the predefined threshold value 778 or at a current limit. Although the threshold value 778 must be exceeded for a switchover to be executed, a current error ΔI can nevertheless be minimized by the operating apparatus and/or by the operating method described herein. The magnitude of the error is dependent upon multiple factors: the selected switchover time point in the current curve I—the steeper the sine curve, the greater the error; the current amplitude of the current curve I—the higher the amplitude, the steeper the ramp, and the greater the error; and a ratio of the switching frequency to the electrical frequency—the smaller the ratio, the greater the error. In all cases, the maximum error is defined by amplitude. This occurs where the current, within a switching frequency, jumps to the maximum current. Although a higher switching frequency reduces the current error, efficiency might be impaired as a result. Minimization of the current error ΔI associated with the operating apparatus described herein and/or the operating method described herein also provides, for example, the following advantages: the gate resistances of switching elements do not need to be rated for a higher current, thereby providing advantages with respect to efficiency. A power loss distribution, for example between MOSFETs and IGBTs, can be maintained, wherein an overloading of one semiconductor type or type of switching element can be prevented.

FIG. 8 shows a schematic time-current intensity diagram 800 for the operation of the at least one switching device according to FIG. 5. The diagram 800 according to FIG. 8 is similar to the diagram according to FIG. 6. Time t is plotted on the x-axis of the diagram 800, and the current intensity i is plotted on the y-axis of the diagram 800. A sinusoidal current curve I is plotted in the diagram 800. A current of a semiconductor or switching element of the switching device, discretized in the form of a pulse P of a pulse-width modulation signal, is further illustrated in FIG. 8. Moreover, potential switchover regions 877 are shown in the diagram 800, in which a switchover can be executed between the actuation of the first switching element by means of the first pulse-width modulation signal and the actuation of the second switching element by means of the second pulse-width modulation signal wherein, according to the example selected here, the predefined threshold value 778 lies between the potential switchover regions 877 and/or outside the potential switchover regions 877. This situation will clarify the employment required of the operating apparatus described herein and/or of the operating method described herein.

Even if the current curve I, according to predictive evaluation, lies ahead of the switchover time point, regulation in the absence of the operating apparatus described herein and/or the operating method described herein would be required in order to opt for a switchover time point or a potential switchover region 877. This might result in a current error associated with an inflexible switchover in response to current limits, as the desired switchover time point or predefined threshold value 778 lies between two pulses P. By the employment of the operating apparatus and/or of the method described herein, an accurate power loss distribution between switching elements, for example MOSFETs and IGBTs can be achieved, thereby generating an advantageous effect, particularly with respect to low ratios between the switching frequency and electrical frequency.

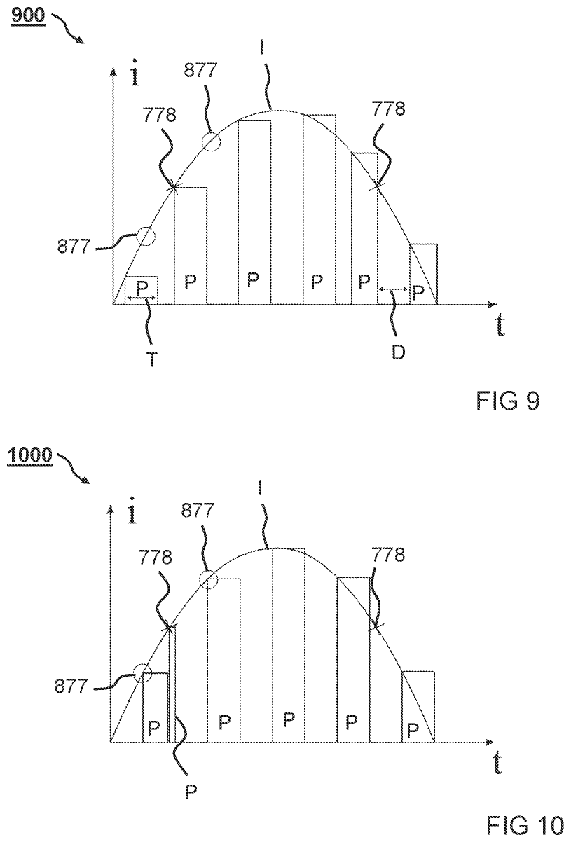

FIG. 9 shows a schematic time-current intensity diagram 900 for the operation of the at least one switching device according to FIG. 5. The diagram 900 according to FIG. 9 corresponds to the diagram according to FIG. 8, with the exception that, in the diagram 900 according to FIG. 9, additionally to the representation according to FIG. 8, a pulse duration T of at least one pulse P and a pulse interval D between pulses P are plotted wherein, by means of the operating apparatus described herein and/or the operating method described herein, at least one parameter of the pulse-width modulation signal illustrated herein is/are adjusted according to the time point of achievement of the predefined threshold value 778. According to one exemplary embodiment, in the actuation step of the operating method and/or by means of the actuation device of the operating apparatus, a pulse-pause ratio and/or a duty factor of the respective pulse-width modulation signal can be variably adjusted. According to the exemplary embodiment represented here, in the actuation step of the method and/or by means of the actuation device of the operating apparatus, the pulse duration T of at least one pulse P and/or the pulse interval between pulses P of the respective pulse-width modulation signal is/are varied. The commencement of a pulse P, in this case the second pulse P represented, thus coincides with the achievement of the predefined threshold value 778.

In order to minimize the current error, or for the more accurate definition of the switchover time point, a discontinuous pulse-width modulation is thus executed by means of the operating apparatus described herein and/or the operating method described herein. Pulse-width modulation is varied, such that the pulse-pause ratio is not constant. The pulse P ahead of the switchover threshold or the predefined threshold value 778 is either shortened or extended, such that the switch-on pulse coincides with the switchover current. The switchover can thus be executed on a rising edge, at the threshold value 778 plotted on the left-hand side of FIG. 9, on the switch itself, or on a falling edge, at the threshold value 778 plotted on the right-hand side of FIG. 9, by means of the complementary switch. According to one exemplary embodiment, in the actuation step of the operating method and/or by means of the actuation device of the operating apparatus, a pulse duration T of a final pulse P of a pulse-width modulation signal prior to the achievement of the predefined threshold value 778 can be varied, such that a first pulse P of the other pulse-width modulation signal commences at the time of achievement of the predefined threshold value 778.

In order to prevent any load unbalance between high-side and low-side switches, the switch-on times of switches or switching elements are equalized. If the first high-side pulse P is extended, the second pulse P can be shortened. Thus, according to one exemplary embodiment, in the actuation step of the operating method and/or by means of the actuation device of the operating apparatus, a pulse duration T of pulses P of the respective pulse-width modulation signal can be adjusted such that a sum of values by which pulses P are shortened and a sum of values by which pulses P are extended are equal.

FIG. 10 shows a schematic time-current intensity diagram 1000 for the operation of at least one switching device according to FIG. 5. The diagram 1000 according to FIG. 10 corresponds to the diagram according to FIG. 8, with the exception that, in the diagram 1000 according to FIG. 10, additionally to the representation according to FIG. 8, an additional pulse P is plotted wherein, by means of the operating apparatus described herein and/or the operating method described herein, at least one parameter of the pulse-width modulation signal represented here is or can be adjusted according to a time point of achievement of the predefined threshold value 778. According to one exemplary embodiment, in the actuation step of the operating method and/or by means of the actuation device of the operating apparatus, a pulse-pause ratio and/or a duty factor of the respective pulse-width modulation signal is/are variably adjusted. In this regard, the diagram 1000 according to FIG. 10 also resembles the diagram according to FIG. 9.

According to the exemplary embodiment represented here, in the actuation step of the operating method and/or by means of the actuation device of the operating apparatus, a pulse number of pulses P of the respective pulse-width modulation signal is varied. In particular, a pulse number of pulses P of one of the pulse-width modulation signals, prior to the achievement of the predefined threshold value 778, is varied such that a first pulse P of the other pulse-width modulation signal commences at the time of achievement of the predefined threshold value 778. An additional pulse P is interpolated, such that a switchover is executed further to an additional pulse P. Immediately in advance of switchover, in this case, the first switching element, for example the SiC MOSFET, is switched off, and a switchover or changeover to the second switching element, for example the IGBT, is executed. In the representation according to FIG. 10, it can be seen that, between the first pulse P represented and the third pulse P represented, a second pulse P having a shorter pulse duration or pulse width is additionally interpolated.

### REFERENCE SYMBOLS

100 Motor vehicle
105 Wheels
110 Electrical energy store
120 Electrical axle drive
125 Power converter system
130 Power converter
140 Electrical machine
150 Transmission device
160 Operating apparatus or apparatus for operation
231 DC terminals
233 DC link capacitor
235 Power modules
237 AC terminals
PWM1 First pulse-width modulation signal
PWM2 Second pulse-width modulation signal
S1 First switching device
S2 Second switching device
S3 Third switching device
S4 Fourth switching device
S5 Fifth switching device
S6 Sixth switching device
362 Read-in device
364 Actuation device
X Current flux signal
400 Operating method
462 Read-in step
464 Actuation step
571 First terminal
572 Second terminal
573 First control terminal
574 Second control terminal
575 First switching element
576 Second switching element
600 Time-current intensity diagram
i Current intensity
I Current curve
t Time
675 First actuation region
676 Second actuation region
677
778 Predefined threshold value
P Pulses
800 Time-current intensity diagram
877 Potential switchover region
900 Time-current intensity diagram
D Pulse interval
T Pulse duration or pulse width
1000 Time-current intensity diagram

1. A method for operating at least one switching device of a power converter for an electrical axle drive of a motor vehicle, wherein the switching device comprises at least two parallel-connected or connectable switching elements that are configured as different types of switching elements, the method comprising:
actuating a first switching element of the switching device by a first pulse-width modulation signal in response to a current flux in the switching device being below a predefined threshold value, or actuating a second switching element of the switching device by a second pulse-width modulation signal in response to the current flux in the switching device exceeding the predefined threshold value; and
adjusting at least one parameter of the first pulse-width modulation signal and/or the second pulse-width modulation signal according to a time point of achievement of the predefined threshold value.

2. The method according to claim 1, wherein adjusting the at least one parameter comprises variably adjusting a pulse-pause ratio of the first pulse-width modulation signal and/or the second pulse-width modulation signal.

3. The method according to claim 1, wherein adjusting the at least one parameter comprises variably adjusting a duty factor of the first pulse-width modulation signal and/or the second pulse-width modulation signal.

4. The method according to claim 1, wherein adjusting the at least one parameter comprises varying a pulse duration of at least one pulse and/or a pulse interval between pulses and/or a pulse number of pulses of the first pulse-width modulation signal and/or the second pulse-width modulation signal.

5. The method according to claim 1, wherein adjusting the at least one parameter comprises varying a pulse duration of a final pulse of one of the first pulse-width modulation signal or the second pulse-width modulation signal prior to achievement of the predefined threshold value, such that a first pulse of the other pulse-width modulation signal commences at a time of achievement of the predefined threshold value.

6. The method according to claim 1, wherein adjusting the at least one parameter comprises adjusting a pulse duration of pulses of the first pulse-width modulation signal and/or of the second pulse-width modulation signal such that a sum of values by which pulses can be shortened and a sum of values by which pulses can be extended are equal.

7. The method according to claim 1, wherein adjusting the at least one parameter comprises varying a pulse number of pulses of one of the first pulse-width modulation signal or the second pulse-width modulation signal prior to achievement of the predefined threshold value such that a first pulse of the other pulse-width modulation signal commences at a time of achievement of the predefined threshold value.

8. The method according to claim 1, comprising:
reading in a current flux signal, which represents the current flux in the switching device as an estimated value, as a measured value, or as a combination of the estimated value and the measured value.

9. An apparatus for operating at least one switching device, comprising:
a processing device configured to:
actuate a first switching element of the switching device by a first pulse-width modulation signal in response to a current flux in the switching device being below a predefined threshold value;
actuate a second switching element of the switching device by a second pulse-width modulation signal in response to the current flux in the switching device exceeding the predefined threshold value; and
adjust at least one parameter of the first pulse-width modulation signal and/or the second pulse-width modulation signal according to a time point of achievement of the predefined threshold value.

10. The apparatus according to claim 9, wherein the processing device is configured to adjust the at least one parameter by variably adjusting a pulse-pause ratio or a duty factor of the first pulse-width modulation signal and/or the second pulse-width modulation signal.

11. The apparatus according to claim 9, wherein the processing device is configured to adjust the at least one parameter by varying a pulse duration of at least one pulse and/or a pulse interval between pulses and/or a pulse number of pulses of the first pulse-width modulation signal and/or the second pulse-width modulation signal.

12. The apparatus according to claim 9, wherein the processing device is configured to adjust the at least one parameter by varying a pulse duration of a final pulse of one of the first pulse-width modulation signal or the second pulse-widge modulation signal prior to achievement of the predefined threshold value, such that a first pulse of the other pulse-width modulation signal commences at a time of achievement of the predefined threshold value.

13. The apparatus according to claim 9, wherein the processing device is configured to adjust the at least one parameter by adjusting a pulse duration of pulses of the first pulse-width modulation signal and/or of the second pulse-width modulation signal such that a sum of values by which pulses can be shortened and a sum of values by which pulses can be extended are equal.

14. The apparatus according to claim 9, wherein the processing device is configured to adjust the at least one parameter by varying a pulse number of pulses of one of the first pulse-width modulation signal or the second pulse-width modulation signal prior to achievement of the predefined threshold value such that a first pulse of the other pulse-width modulation signal commences at a time of achievement of the predefined threshold value.

15. The apparatus according to claim 9, wherein the processing device is configured to:
read in a current flux signal, which represents the current flux in the switching device as an estimated value, as a measured value, or as a combination of the estimated value and the measured value.

16. A power converter system for an electrical axle drive of a motor vehicle, the power converter system comprising the apparatus according to claim 9 and a power converter, wherein the power converter comprises the at least one switching device, which comprises at least two parallel-connected switching elements that are different types of switching elements.

17. The power converter system according to claim 16, wherein the first switching element is a field effect transistor, a metal oxide semiconductor field effect transistor, or a silicon carbide metal oxide field effect transistor, and wherein the second switching element is a bipolar transistor, a bipolar transistor with an insulated gate electrode, or a silicon bipolar transistor with an insulated gate electrode.

18. An electrical axle drive for a motor vehicle, wherein the electrical axle drive comprises:
at least one electrical machine;
a transmission device; and
the power converter system according to claim 16.

19. A motor vehicle comprising the power converter system according to claim 16.

20. A non-transitory machine-readable storage medium having stored thereon computer program instructions that, when executed by a computing device, cause the computing device to perform a method comprising:
actuating a first switching element of a switching device by a first pulse-width modulation signal in response to a current flux in the switching device being below a predefined threshold value, or actuating a second switching element of the switching device by a second pulse-width modulation signal in response to the current flux in the switching device exceeding the predefined threshold value; and
adjusting at least one parameter of the first pulse-width modulation signal and/or the second pulse-width modulation signal according to a time point of achievement of the predefined threshold value.
